(19) United States
(12) Patent Application Publication
(10) Pub. No.: US 2013/0187189 A1
(43) Pub. Date: Jul. 25, 2013

(54) HEAT SINK BIMETALLIC PILLAR BUMP AND THE LED HAVING THE SAME

(71) Applicant: Taiwan Electric Contacts Corp., NEW TAIPEI CITY (TW)

(72) Inventors: MING-CHANG LIN, NEW TAIPEI CITY (TW); MING CHEN TSAI, NEW TAIPEI CITY (TW)

(73) Assignee: TAIWAN ELECTRIC CONTACTS CORP., NEW TAIPEI CITY (TW)

(21) Appl. No.: 13/744,901

(22) Filed: Jan. 18, 2013

(30) Foreign Application Priority Data
Jan. 19, 2012 (TW) 101102147

(51) Int. Cl. H01L 33/64

(52) U.S. Cl. CPC H01L 33/641
USPC 257/99; 165/185

(57) ABSTRACT

The invention relates to a heat sink bimetallic pillar bump that is mainly disposed inside of a LED. The heat sink bimetallic pillar bump comprises a heat absorbing section composed of a first metal and a heat dissipating section firmly connected with the heat absorbing section. The heat dissipating section is composed of a second metal. The first metal has a thermal conductivity greater than that of the second metal. The LED chip is disposed on the heat absorbing section. The heat absorbing section with high thermal conductivity quickly transfers the heat generated by the LED chip to the heat dissipating section. This makes the heat from the LED chip to be dissipated quickly, which therefore achieves purposes of improving the heat dissipation efficiency of the LED and other kinds of IC chips and prolonging the lifespan of the LED and other kinds of IC chips.

### BACKGROUND OF INVENTION

1. Field of Invention

The invention relates to heat sink of the LED, and more especially to a heat sink bimetallic pillar bump for dissipating a chip of the LED or other kinds of IC chips.

2. Related Prior Art

A developed illuminating device is a type of electroluminescence device, which benefits environment-friendly advantages, energy savings and long lifespan. According to the present technology, the LED might have 75-85% efficiency at emitting light that would be converted to heat. When the heat cannot be dissipated efficiently, the luminous efficiency and the lifespan of the LED would be highly degraded.

FIG. 10 is a conventional heat sink of the LED 9. The LED 9 has a base 90. A heat sink Cu pillar bump 91 is disposed inside of the base 90 of the LED 9. The top portion 910 of the heat sink Cu pillar bump 91 is an indentation for support a chip 92 thereon. The bottom portion 911 of the heat sink Cu pillar bump 91 is exposed outside of the base 90 and contacts with a thermal conductive circuit board 8, such as a high thermal conductive aluminum circuit board. The heat generated by the chip 92 is transferred from the heat sink Cu pillar bump 91 to the circuit board 8, and then the heat is dissipated by a heat sink (not shown). The heat sink Cu pillar bump 91 is generally made by a copper, which cannot quickly transfer the heat generated by the chip 92 to the circuit board 8. This causes that the heat from the chip 92 cannot be dissipated quickly. Thus, the luminous efficiency of the chip 92 would be there declined, or the chip 92 would be damaged earlier, and therefore the lifespan of the LED is seriously affected.

### SUMMARY OF INVENTION

In order to solve the problems mentioned above, the present invention discloses a heat sink bimetallic pillar bump applicable for LED chip and other kinds of IC chips, which includes a heat absorbing section composed of a first metal and a heat dissipating section composed of a second metal, The first metal has a thermal conductivity greater than that of the second metal. The heat absorbing section is closely connected with the heat dissipating section. Preferably, the first metal is selected from the group of copper, silver, copper alloy and silver alloy, and the second metal is selected from the group of copper, aluminum, copper alloy and aluminum alloy.

When the heat sink bimetallic pillar bump is applied to a LED, the chip of the LED is located on the absorbing section with high thermal conductivity. The heat absorbing section quickly transfers the heat generated by the LED chip to the heat dissipating section. This makes the heat from the LED chip to be dissipated quickly, which therefore solves the problems mentioned in the related prior art. Accordingly, the present invention achieves purposes of improving the heat dissipation efficiency of the LED and other kinds of IC chips and prolonging the lifespan of the LED and other kinds of IC chips.

Preferably, the top portion of the heat dissipating section has a thermal conductive bonding layer (such as layer of solder), and the heat dissipating section is firmly connected with the heat absorbing section via the thermal conductive bonding layer.

Preferably, the heat absorbing section has a top portion with an indentation formed therein and a bottom portion firmly connected with the heat dissipating section.

Preferably, the heat dissipating section of the present invention has a bottom tray and a pillar. The pillar has a bottom extending from a central area of the bottom tray. The heat absorbing section has a top portion with an indentation formed therein and a bottom portion firmly connected with a top of the pillar of the heat dissipating section.

The present invention further discloses a light emitting diode, which at least comprises a base, a heat sink bimetallic pillar bump and a chip. The heat sink bimetallic pillar bump is located inside of the base. The heat sink bimetallic pillar bump includes a heat absorbing section composed of a first metal and a heat dissipating section composed of a second metal, wherein the first metal has a thermal conductivity greater than that of the second metal. The heat dissipating section has a down portion exposed to the outside of the base. The heat absorbing section has a bottom portion firmly connected with an up portion of the heat dissipating section. The heat absorbing section has a top portion with an indentation formed therein. The chip is disposed in the indentation of the heat absorbing section. Preferably, the first metal is selected from the group of copper, silver, copper alloy and silver alloy, and the second metal is selected from the group of copper, aluminum, copper alloy and aluminum alloy. Accordingly, the heat sink bimetallic pillar bump of the present invention would improve the heat dissipation efficiency of the LED and prolong the lifespan thereof.

Other features, objects, aspects and advantages will be identified and described in detail below.

### BRIEF DESCRIPTION OF DRAWINGS

FIG. 1 is a view of a heat sink bimetallic pillar bump in accordance with a first embodiment of the present invention;

FIG. 2 is a view showing that the heat sink bimetallic pillar bump of the first embodiment is applied to a LED;

FIG. 3 is a view showing a manufacturing process of making a heat sink bimetallic pillar bump in accordance with a second embodiment of the present invention;

FIG. 4 is a view of a heat sink bimetallic pillar bump in accordance with a third embodiment of the present invention;

FIG. 5 is a view of a heat sink bimetallic pillar bump in accordance with a fourth embodiment of the present invention;

FIG. 6 is a view of a heat sink bimetallic pillar bump in accordance with a fifth embodiment of the present invention;

FIGS. 7 and 7A are a view showing the test result of the heat sink bimetallic pillar bump in closed space;

FIGS. 8 and 8A are a view showing the test result of the heat sink bimetallic pillar bump in open space;

FIG. 9 is a view showing the thermal resistance measurement of the conventional heat sink and the heat sink bimetallic pillar bump; and

FIG. 10 is a view of a conventional heat sink of the LED.

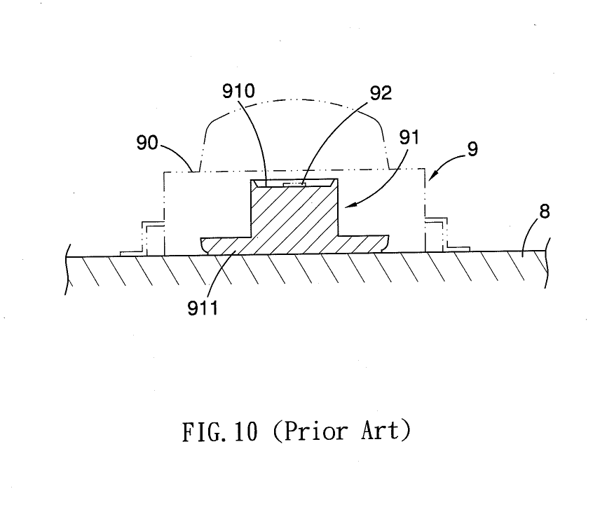

### DETAILED DESCRIPTION OF EMBODIMENTS

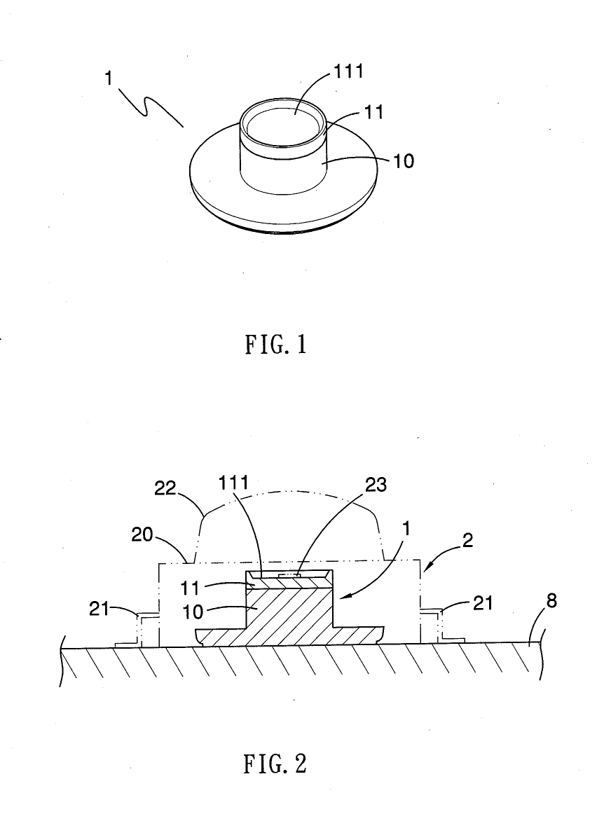

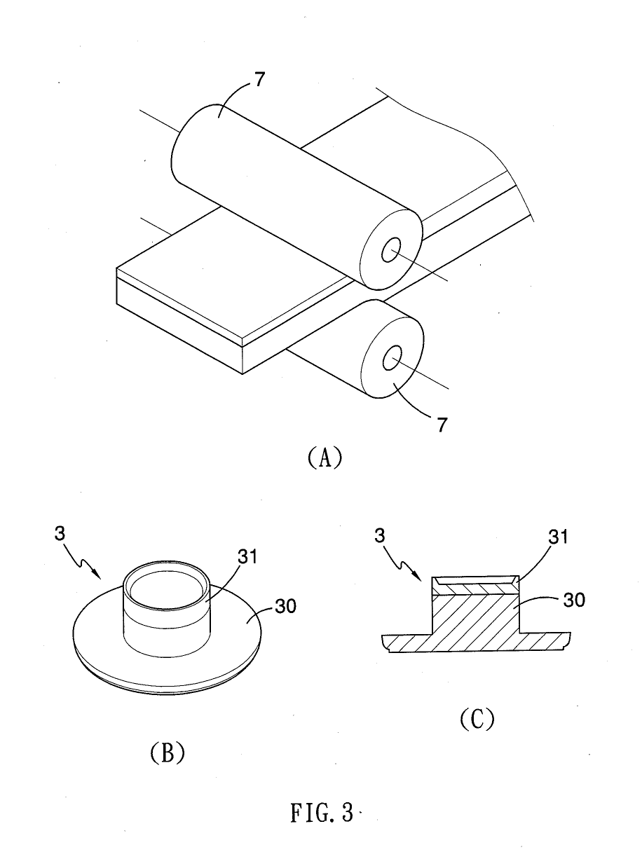

With reference to FIG. 1, a heat sink bimetallic pillar bump 1 is shown in accordance with a first embodiment of the present invention. With reference to FIG. 2, the heat sink bimetallic pillar bump 1 of the first embodiment applied to, but not limited to, a LED 2 is shown. Alternatively, the heat sink bimetallic pillar bump 1 can be also applied to any kinds of IC chips for dissipating. The heat sink bimetallic pillar bump 1 includes a heat dissipating section 10 and heat absorbing section 11. The heat dissipating section 10 is composed of a second metal. The heat absorbing section 11 is composed of a first metal having a thermal conductivity greater than that of the second metal, and firmly connected with the heat dissipating section 10. Preferably, the first metal is selected from the group of copper, silver, copper alloy and silver alloy, and the second metal is selected from the group of copper, aluminum, copper alloy and aluminum alloy. The heat sink bimetallic pillar bump 1 can be further performed an electroplating treatment if necessary. Besides, the heat sink bimetallic pillar bump I can be prepared by a technology, such as a forging process.

The LED 2 includes a base 20, a pair of leads 21, a lens 22, a chip 23 and a heat sink bimetallic pillar bump 1. In this embodiment, the LED 2 is disposed on a thermal conductive circuit board 8 by a surface-mount technology. The heat sink bimetallic pillar bump 1 is located inside of the base 20, and the bottom of the heat dissipating section 10 is in contact with the circuit board 8. The chip 23 is disposed on the indentation 111 of the heat absorbing section 11 of the heat sink bimetallic pillar bump 1. When the chip 23 is operated, the heat generated by the chip 23 is transferred from the heat absorbing section 11 and the heat dissipating section 10 to circuit board 8, and then the heat would be dissipated by a set of heat sink fins (not shown) thermally conductively connected with the circuit board 8.

As a result of the thermal conductivity of the heat absorbing section 11 greater than that of the heat dissipating section 10, the heat absorbing section 11 quickly absorbs the heat generated by the chip 23 and transfers to the heat dissipating section 10. This would make the heat from the chip 23 to be quickly dissipated, and therefore achieves the purposes of improving the heat dissipation efficiency of the LED 2 and prolonging the lifespan thereof.

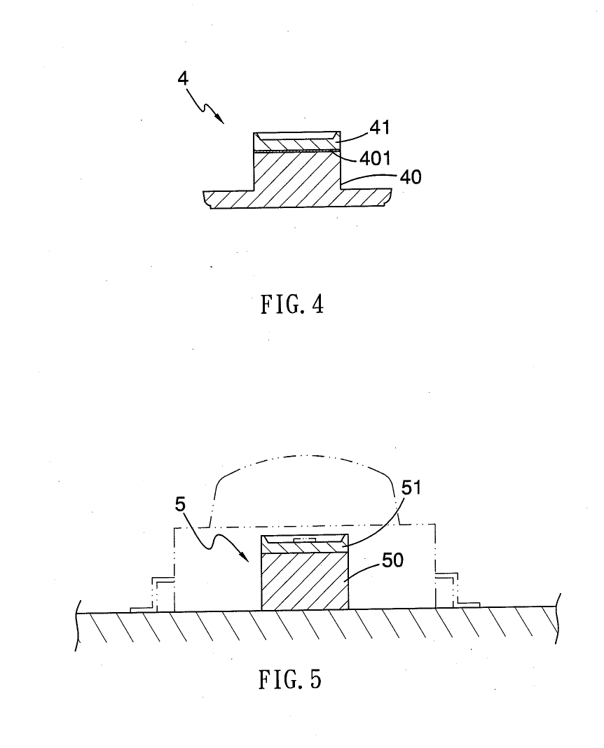

With reference to FIG. 3, a manufacturing process of making a heat sink bimetallic pillar bump is shown in accordance with a second embodiment of the present invention. The heat sink bimetallic pillar bump 3 has a heat dissipating section 30 and a heat absorbing section 31, which are similar to the heat dissipating section 10 and heat absorbing section 11 of the heat sink bimetallic pillar bump 1 mentioned above (as shown in FIG. 1). The difference is that there is a plastic flow generated in the interface between the heat dissipating section 30 and the heat absorbing section 31 by applying an external mechanical force onto the heat dissipating section 30 and the heat absorbing section 31. This is because a rolling process is used during the processes of making the heat sink bimetallic pillar bump 3. More specifically, as shown in FIG. 3(A), the second metal sheet (the lower sheet) used for forming the heat dissipating section 30 and the first metal sheet (the upper sheet) used for forming the heat absorbing section 31 are first performed a surface roughening process and then fed in between two rollers 7 of the rolling method, so as to enable the first metal sheet and the second metal sheet to be tightly bonded with each other. At this time, the first metal sheet and the second metal sheet are bonded with each other because of the plastic flow, which achieves the aforementioned tight bonding. After that, as shown in FIGS. 3(B) and 3(C), a punching process is performed on the first metal sheet and the second metal sheet that are connected with each other to form a heat sink bimetallic pillar bump 3. In other embodiment, a cold heading process, a cold welding process, a hot pressing process or other process can be also applicable to the process of forming the heat sink bimetallic pillar bump 3 except the aforementioned rolling process.

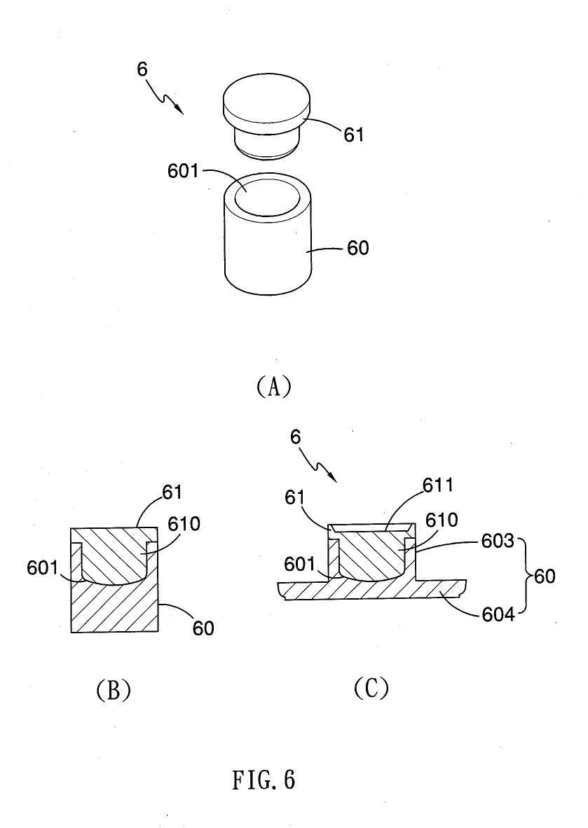

With reference to FIG. 4, a heat sink bimetallic pillar bump 4 is shown in accordance with a third embodiment of the present invention. The heat sink bimetallic pillar bump 4 has a heat dissipating section 40 and a heat absorbing section 41, which are similar to the heat dissipating section 30 and heat absorbing section 31 of the heat sink bimetallic pillar bump 3 mentioned in the second embodiment (as shown in FIG. 3). The difference is that the heat sink bimetallic pillar bump 4 further has a thermal conductive bonding layer 401 located between the up portion of the heat dissipating section 40 and the bottom portion of the heat absorbing section 41. Specifically, the thermal conductive bonding layer 401 is used to tightly bond the heat dissipating section 40 with the heat absorbing section 41 by performing a welding process. In short, the thermal conductive bonding layer 401 is substantially a layer of solder.

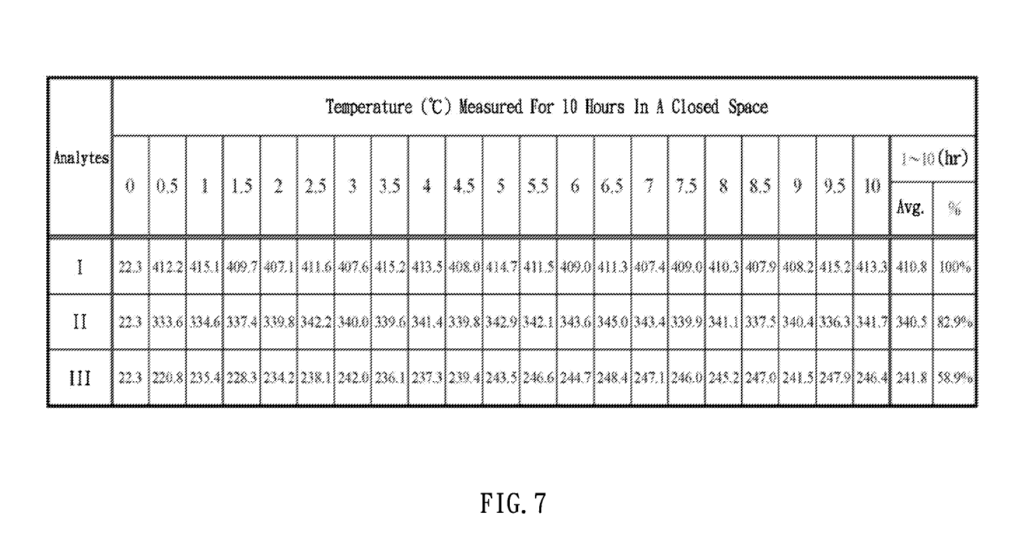

With reference of FIG. 5, a heat sink bimetallic pillar bump 5 is shown in accordance with a fourth embodiment of the present invention. The heat sink bimetallic pillar bump 5 has a heat dissipating section 50 and a heat absorbing section 51, which are similar to the heat dissipating section 30 and heat absorbing section 31 of the heat sink bimetallic pillar bump 3 mentioned in the second embodiment (as shown in FIG. 3). The difference between them is that there is no bottom tray mentioned above in the heat sink bimetallic pillar bump 5.

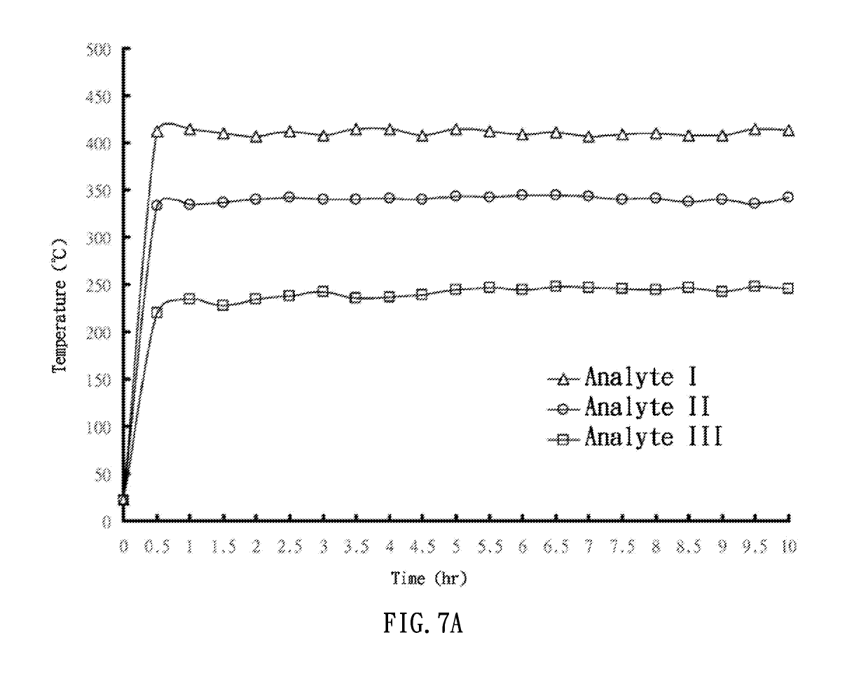

With reference to FIG. 6, a heat sink bimetallic pillar bump 6 is shown in accordance with a fifth embodiment of the present invention. Firstly, as shown in FIG. 6(A), the heat dissipating section 60 and the heat absorbing section 61 are two independent components, which are respectively formed by a punching process. The above mentioned heat dissipating section 60 has an up portion with a circular hole 601 formed therein. After that, as shown in FIG. 6(B), the heat absorbing section 61 has a first portion 610 firmly stuffed in the circular hole 601. In this embodiment, the down portion of the heat absorbing section 61 is disposed in the circular hole 601, and the rest portions of the heat absorbing section 61 are located outside of the circular hole 601. Finally, a punching process is performed on the heat dissipating section 60 and the heat absorbing section 61 to form a heat sink bimetallic pillar bump 6 shown in FIG. 6(C). The configurations, applications and functions of heat sink bimetallic pillar bump 6 have been illustrated as above, which are not redundantly described herein. The configurations of the heat absorbing section 61 and the heat dissipating section 60 are formed in the above-mentioned punching process.

As shown in FIG. 6(C) of the heat sink bimetallic pillar bump 6 manufactured by the aforementioned process, the first portion 610 of the heat absorbing section 61 is firmly stuffed in the circular hole 601 completely, which forms a close connection between the heat dissipating section 60 and the heat absorbing section 61. In addition, the heat absorbing section 61 has a top portion with an indentation 611 formed therein to support a chip. Preferably, the heat dissipating section 60 has a bottom tray 604 and a pillar 603. The pillar 603 has a bottom extending from a central area of the bottom tray 604. The heat absorbing section 61 further has a bottom portion firmly connected with a top of the pillar 603 of the heat dissipating section 60. In this embodiment, the bottom portion of the heat absorbing section 61 is firmly and completely stuffed in the circular hole 601 in the top of the pillar 603.

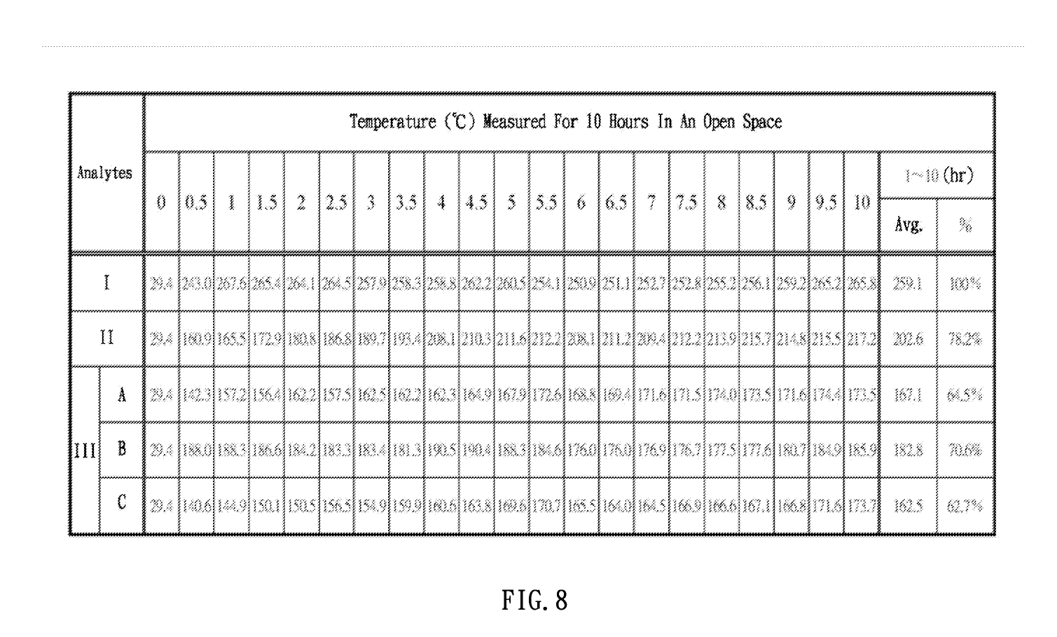

With reference of FIGS. 7 and 7A, the result of testing the heat sink bimetallic pillar bump in closed space is shown. As shown in FIGS. 7 and 7A, Analyte I represents the heat source, Analyte II represents the conventional heat sink pillar bump and Analyte III represents the heat sink bimetallic pillar bump (including the heat absorbing section made by copper and the heat dissipating section made by aluminum) of the present invention. The test method is illustrated as below. The conventional heat sink pillar bump (made by pure copper) mentioned in the related prior art and the heat sink bimetallic pillar bump (including the heat absorbing section made by copper and the heat dissipating section made by aluminum) of the present invention are heated up by a heat source of average temperature at 410.8 degree C. for 10 hours. These test data are recorded for each half hour. The conventional heat sink pillar bump has worse efficiency of heat dissipation, which incurs the problems of dissipating heat in time. The detailed test result shows that the average temperature of the conventional heat sink pillar bump is 340.5 degree C. after heating up for 10 hours. Compared with the conventional heat sink pillar bump, the heat sink bimetallic pillar bump of the present invention has better efficiency of heat dissipation than the conventional heat sink pillar bump because of the copper with properties of greater heat transmission (401 J/m². K. s) and less heat dissipation (heat capacity of copper is 0.8188 cal/cm³-° C.) and the aluminum with properties of less heat transmission (237 J/m². K. s) and greater heat dissipation (heat capacity of aluminum is 0.5859 cal/cm³-° C.). From the test result, the average temperature of the heat sink bimetallic pillar bump of the present invention is 241.8 degree C., which drops 98.7 degree C. (falls about 24%), after heating up by the heat source for 10 hours. This shows that the heat sink bimetallic pillar bump of the present invention has greater efficiency of heat dissipation and has benefits of prolonging the lifespan of the LED. In addition, the aluminum also has properties of being light, low-priced and easy-manufactured, which can further increase the application and competition of the heat sink bimetallic pillar bump of the present invention.

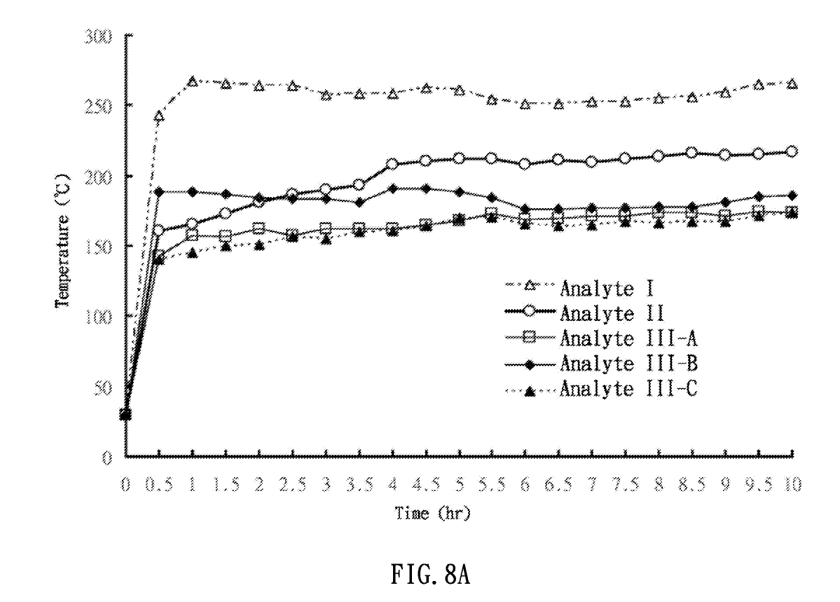

With reference of FIGS. 8 and 8A, the result of testing the heat sink bimetallic pillar bump in open space is shown. As shown in FIGS. 8 and 8A, Analyte I represents the heat source, and Analyte II represents the conventional heat sink pillar bump. Analyte III represents the heat sink bimetallic pillar bump of the present invention, more specifically, Analyte III-A represents the heat sink bimetallic pillar bump including the copper heat absorbing section and the aluminum heat dissipating section, Analyte III-B represents the heat sink bimetallic pillar bump including the silver heat absorbing section and the copper heat dissipating section, and Analyte III-C represents the heat sink bimetallic pillar bump including the silver heat absorbing section and the aluminum heat dissipating section. The detailed test method is illustrated as below. The conventional heat sink pillar bump (made by pure copper) mentioned in the related prior art and the heat sink bimetallic pillar bump (including the heat absorbing section made by copper and the heat dissipating section made by aluminum) of the present invention are heated up by a heat source of average temperature at 259.1 degree C. for 10 hours. These test data are recorded for each half hour. The test result shows that the temperature of the conventional heat sink pillar bump is gradually higher than that of any kind of the heat sink bimetallic pillar bump of the present invention after heating up for three hours, which evidences deterioration of temperature rising property of the conventional heat sink pillar bump. The reason why the temperature rising property of the conventional heat sink pillar bump is getting worse may be inferred that the pure copper easily gets oxidized at high temperature. At all events, the test results displays that the efficiency of heat dissipation of the heat sink bimetallic pillar bump in open space is obviously greater than that of the conventional heat sink pillar bump.

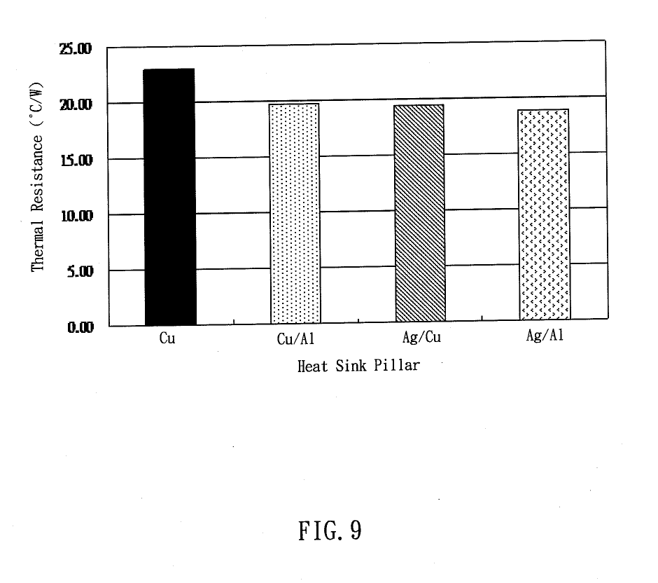

With reference of FIG. 9, the thermal resistance measurement of the conventional heat sink pillar bump and the heat sink bimetallic pillar bump of the present invention is shown. As shown in FIG. 9, Cu represents the conventional heat sink pillar bump that only made by pure copper; Cu/Al represents the heat sink bimetallic pillar bump including the copper heat absorbing section and the aluminum heat dissipating section (hereinafter called as Cu/Al heat sink bimetallic pillar bump); Ag/Cu represents the heat sink bimetallic pillar bump including the silver heat absorbing section and the copper heat dissipating section (hereinafter called as Ag/Cu heat sink bimetallic pillar bump); and Ag/Al represents the heat sink bimetallic pillar bump including the silver heat absorbing section and the aluminum heat dissipating section. (hereinafter called as Ag/Al heat sink bimetallic pillar bump). The measurement shows that the thermal resistance of the conventional heat sink pillar bump made by only pure copper is 22.98° C./W, and the thermal resistance of the Cu/Al heat sink bimetallic pillar bump, the Ag/Cu heat sink bimetallic pillar bump and the Ag/Al heat sink bimetallic pillar bump are 19.7° C./W, 19.46° C./W and 18.86° C./W, respectively. This evidences that the thermal resistance of the conventional heat sink pillar bump made by only pure copper is higher than that of the heat sink bimetallic pillar bump of the present invention, which accordingly means that the heat sink bimetallic pillar bump of the present invention has greater heat dissipation efficiency than the conventional heat sink pillar bump.

It will be appreciated that although a particular embodiment of the invention has been shown and described, modifications may be made. It is intended in the claims to cover such modifications which come within the spirit and scope of the invention.

The invention claimed is:

1. A heat sink bimetallic pillar bump comprising:
a heat absorbing section, composed of a first metal; and
a heat dissipating section, composed of a second metal and closely connected with the heat absorbing section, wherein the first metal has a thermal conductivity greater than that of the second metal.

2. The heat sink bimetallic pillar bump of claim 1, wherein the heat dissipating section has an up portion with a hole formed therein, and one portion of the heat absorbing section is firmly stuffed in the circular hole of the heat dissipating section.

3. The heat sink bimetallic pillar bump of claim 1, wherein the top portion of the heat dissipating section has a thermal conductive bonding layer, and the heat dissipating section is firmly connected with the heat absorbing section via the thermal conductive bonding layer.

4. The heat sink bimetallic pillar bump of claim 1, wherein the first metal is selected from the group of copper, silver, copper alloy and silver alloy, and the second metal is selected from the group of copper, aluminum, copper alloy and aluminum alloy.

5. The heat sink bimetallic pillar bump of claim 1, wherein the heat absorbing section has a top portion with an indentation formed therein and a bottom portion firmly connected with the heat dissipating section.

6. The heat sink bimetallic pillar bump of claim 1, wherein the heat dissipating section has a bottom tray and a pillar, the pillar has a bottom extending from a central area of the bottom tray, the heat absorbing section has a top portion with an indentation formed therein and a bottom portion firmly connected with a top of the pillar of the heat dissipating section.

7. A light emitting diode comprising:
a base;
a heat sink bimetallic pillar bump, located inside of the base, the heat sink bimetallic pillar bump comprising a heat absorbing section composed of a first metal and a heat dissipating section composed of a second metal, wherein the first metal has a thermal conductivity greater than that of the second metal, the heat dissipating section has a down portion exposed outside of the base, the heat absorbing section has a bottom portion firmly connected with an up portion of the heat dissipating section, and the heat absorbing section has a top portion with an indentation formed therein; and
a chip, disposed in the indentation of the heat absorbing section.

8. The light emitting diode of claim 7, wherein the first metal is selected from the group of copper, silver, copper alloy and silver alloy, and the second metal is selected from the group of copper, aluminum, copper alloy and aluminum alloy.
